(19) United States
(12) Patent Application Publication
(10) Pub. No.: US 2007/0019773 A1
(43) Pub. Date: Jan. 25, 2007

(54) Data clock recovery system and method employing phase shifting related to lag or lead time

(76) Inventor: Dacheng (Henry) Zhou, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/186,515

(22) Filed: Jul. 21, 2005

(51) Int. Cl. H03D 3/24

(52) U.S. Cl. 375/373

(57) ABSTRACT

A data clock recovery system is provided. A phase detector is configured to produce a first signal indicating whether a data clock lags or leads a preferred phase of the data clock in relation to an input data stream. A phase controller is configured to process the first signal to shift a phase of the data clock toward the preferred phase at a rate positively related to a length of time the data clock lags or leads the preferred phase.

### BACKGROUND

In virtually all communication systems, data is transferred from a transmitting node of the communication system to a receiving node over a communication path. Such a path may be a wired or wireless connection between the communicating nodes. In many of these systems, the data take the form of a digital signal transferred at a substantially constant rate over the connection. Normally, the data signal presents a series of binary digits (“bits”) that represent the digital information being transmitted to form a serial communication path. Further, several such series of bits transferred simultaneously may form a multi-channel, parallel communication connection.

Some communication systems also supply a data clock signal over the same connection to provide timing information for the data signal. Typically, the data signal is sampled, or “clocked,” at each logic “low” to logic “high” transition of the data clock to identify each bit being transferred. However, other communication systems do not provide a clock signal along with the data signal over the connection, instead relying on the receiving node's knowledge of the transfer rate of the data signal to allow proper interpretation of the data signal.

Unfortunately, drift of the data signal frequency, variations in the frequency of a local oscillator from which the data clock is derived, and similar problems may cause the receiving node to improperly clock the data signal. To counteract such problems, the receiving node is often equipped with a data clock recovery system to help ensure proper sampling of the data signal.

One example of such a system 100 is shown in FIG. 1. A data sampler 102 samples an input data stream 110 received over a communication system connection by way of a data clock 112, resulting in a sampled input data stream 114 for use by the receiving node. The data sampler 102 also compares the phase of the input data stream 110 with the data clock 112 to generate a phase difference signal 118 indicating when the data clock 112 is sampling the input data stream 110 during each bit of the input data stream 110 to yield the sampled input data stream 114. Typically, the data clock 112 is configured to sample the input data stream 110 at substantially the midpoint between transitions of the input data stream 110 to help avoid sampling while the input data stream 110 is transitioning between logic states. The midpoint is often selected as the preferred phase of the data clock 112. Oftentimes, one or more versions of the data clock 112 of varying phase in addition to the data clock 112 are supplied to the data sampler 102 to sample the input data stream 110 at multiple points during each transferred bit to determine whether the data clock 112 transitions are being generated early (“leading”) or late (“lagging”) compared to the preferred phase.

In the particular implementation of FIG. 1, the various versions of the data clock 112 are derived from a multiphase local clock 116 originating in the receiving node. These phases are shown in the timing diagram of FIG. 2 as CP0-CP3, thus indicating that the multiphase clock 116 provides four phases spaced 90 degrees apart. In addition, other phases of the local clock 116 (indicated as CI01-CI03, CI11-CI13, CI21-CI23, and CI31-CI33) are generated by way of a phase interpolator 108 driven by the local clock 116. In the particular example of FIG. 2, sixteen total phases are supplied by the phase interpolator 108, which employs one of these phases as the data clock 112 to produce the sampled data input stream 114.

The phase difference signal 118 generated by the data sampler 102 indicates the phase relationship between the data clock 112 and the input data stream 110, thus signifying whether the data clock 112 is leading or lagging its preferred phase. In turn, a counter 104 takes the phase difference signal 118 as input to produce a phase count 120, which accumulates the phase indications provided by the phase difference signal 118. More specifically, for each bit period in which the data clock 112 lags its preferred phase, the counter 104 increments the phase count 120 by one. Conversely, for each bit period in which the data clock 112 leads the preferred phase, the counter 104 decrements the phase count 120 by one.

In further reference to FIG. 1, a threshold comparator 106 compares the phase count 120 with a threshold value. The threshold value is typically utilized to prevent unnecessary adjustments in the phase of the data clock 112 in reaction to noise or temporary phase misalignment between the data clock 112 and the input data stream 110. If the phase count 120 exceeds the threshold, or falls below the negative of the threshold, the threshold comparator 106 produces a pulse on a phase shift signal 122 to either advance or delay the phase of the data clock 112, depending on the sign of the phase count 120. Once the pulse on the phase shift sign 122 is generated, the counter 104 resets the phase count 120 to zero. In one example, the phase shift signal 122 includes two separate signal lines, with one line providing pulses to delay the phase of the data clock 112 by a portion of a period, and another line supplying pulses to advance the phase of the data clock 112 by a portion of a period.

The phase shift signal 122 is accepted as input by the phase interpolator 108, described above, to drive the data clock 112 with the appropriate phase of the local clock 116 or any of its interpolated phases, as depicted in FIG. 2. For example, if the data clock 112 is currently derived from interpolated clock phase CI22, and the phase shift signal 122 indicates that the phase of the data clock 112 utilized to produce the sampled input data stream 114 should be delayed, the phase interpolator 108 begins deriving the data clock 112 from interpolated clock phase CI23. Adjusting the phase in this manner allows the rising transitions of the data clock 112 to more closely align with the midpoint of each bit period of the input data stream 110.

FIG. 3 presents an idealized timing diagram of a particular scenario in which the frequency of the input data stream 110 is slightly higher than that of the data clock 112, thus requiring a continuing adjustment in the phase of the data clock 112. The phase difference signal 118 indicates during each period of the data clock 112 whether the data clock 112 leads or lags its preferred phase, wherein the rising edge of the data clock 112 is aligned midway between input data stream 110 transitions. The preferred phase in this example is shown by way of vertical dotted lines in FIG. 3. Due to the frequency difference, each bit period displayed shows the data clock 112 lagging its preferred phase. Accordingly, the phase count 120 counts from zero past a threshold value of 64, at which point the threshold comparator 106 generates a pulse on the phase shift signal 122 to advance the phase of the data clock 112 by one of the interpolated phases of the phase interpolator 108. The counter 104 also resets the phase count 120 to zero. Since the data clock 112 still lags its preferred phase, as indicated by the phase difference signal 118 from the data sampler 102, the counter 104 increments the phase count 120 once per bit period from zero past the threshold. At that point, the threshold comparator 106 issues another pulse on the phase shift signal 122 to advance the data clock 112 another step. The counter 104 is reset once again, and the process continues in this fashion to maintain the phase of the data clock 112 at or near its preferred phase.

However, greater frequency differences between the input data stream 110 and the data clock 112 may prevent the data clock 112 from maintaining its preferred phase, as the rate at which the phase of the data clock 112 is adjusted is limited. More specifically, due to the effect of the threshold and the updating of the phase of the data clock 112 once per cycle of the counter 104, the phase of the data clock 112 may be adjusted at most once per a number of bit periods equal to the threshold.

### SUMMARY

One embodiment of the present invention provides a data clock recovery system for a communication system. A phase detector is configured to produce a first signal indicating whether a data clock lags or leads a preferred phase in relation to an input data stream. A phase controller is configured to process the first signal to shift a phase of the data clock toward the preferred phase at a rate positively related to a length of time the data clock lags or leads the preferred phase.

In another embodiment of the invention, a method for recovering data clock information from a communication signal is provided. A first signal indicating whether a data clock lags or leads a preferred phase in relation to an input data stream is generated. A phase of the data clock is advanced at a rate positively related to a first length of time the first signal indicates the data clock lags the preferred phase. Conversely, the phase of the data clock is delayed at a rate positively related to a second length of time the first signal indicates the data clock leads the preferred phase.

Additional embodiments and advantages of the present invention will be realized by those skilled in the art upon perusal of the following detailed description, taken in conjunction with the accompanying drawings.

### BRIEF DESCRIPTION OF THE DRAWINGS

FIG. 1 is a block diagram of a data clock recovery system from the prior art.

FIG. 2 is a timing diagram of a multiphase clock generated by a phase interpolator of the data clock recovery system of FIG. 1 from the prior art.

FIG. 3 is a simplified timing diagram illustrating the operation of the data clock recovery system of FIG. 1 from the prior art.

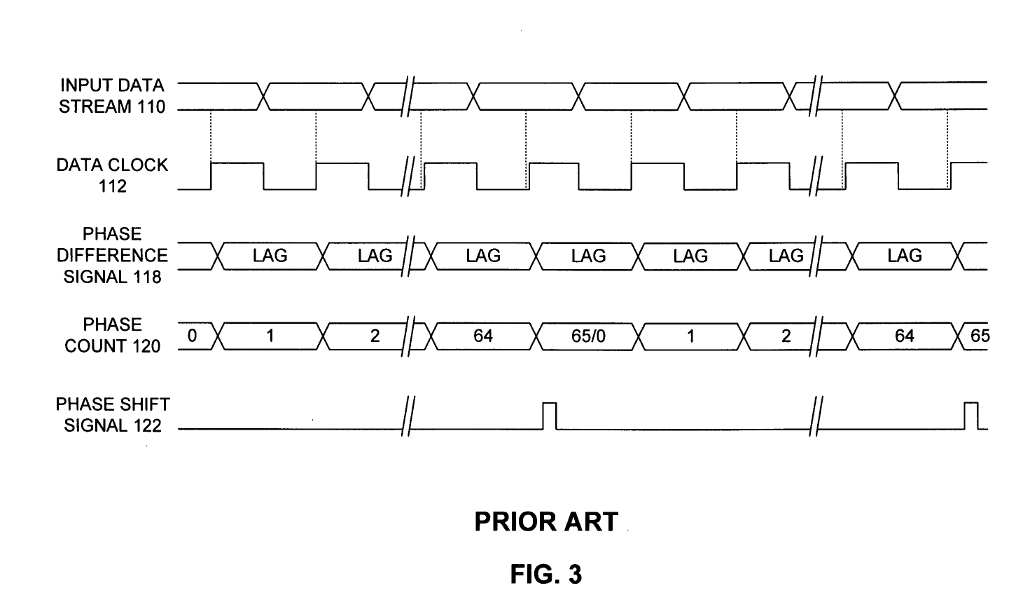

FIG. 4 is a block diagram of a data clock recovery system according to an embodiment of the invention.

FIG. 5 is a block diagram of a phase controller employed by the data clock recovery system of FIG. 4 according to a particular embodiment of the invention.

FIG. 6 is a simplified timing diagram illustrating the operation of the data clock recovery system of FIG. 4 employing the phase controller of FIG. 5 according to an embodiment of the invention.

FIG. 7 is a flow chart of a method for recovering clock information from a communication signal according to an embodiment of the invention.

FIG. 8 is a flow chart of delaying or advancing a phase of a data clock employed in the method of FIG. 7 according to an embodiment of the invention.

### DETAILED DESCRIPTION

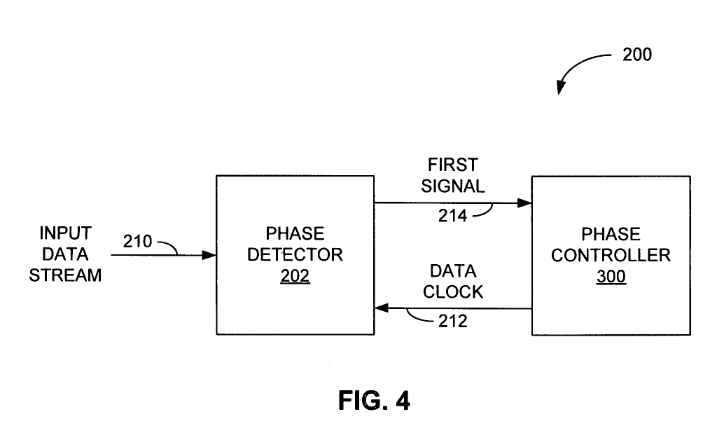

One embodiment of a data clock recovery system 200 is presented in FIG. 4. Generally, a phase detector 202 is configured to produce a first signal 214 indicating whether a data clock 212 lags or leads a preferred phase in relation to an input data stream 210. In one embodiment, the input data stream 210 is received over a communication system connection or path. Also, in one implementation, the preferred phase of the data clock 212 is a midpoint between logical transitions of the input data stream 210. The system 200 also includes a phase controller 300 configured to process the first signal 214 to shift the phase of the data clock 212 toward the preferred phase at a rate positively related to a length of time the data clock lags or leads the preferred phase. In other words, the rate of the phase shift of the data clock 212 generally increases while the data clock 212 continues to lag or lead the preferred phase.

In one embodiment, the phase of the data clock 212 is to be adjusted via the phase controller 300 to sample the input data stream 210 once per bit period substantially at the midpoint between transitions of the input data stream 210 in order to avoid sampling at or near logic state transitions of the input data stream 210. In one particular implementation, an additional version of the data clock 212, separated in phase from the data clock 212 by 180 degrees, is supplied by the phase controller 300 to the phase detector 202 to sample the input data stream 210 at or near the logic transitions of the input data stream 210. Use of this additional phase allows the phase detector 202 to compare the input data stream 210 near its logic transitions and midway between to help determine whether the data clock 212 leads or lags the midpoint of the current bit period of the input data stream 210. In alternative embodiments, more versions the data clock 212 of varying phase may be employed to provide more detailed information concerning the phase difference between the data clock 212 and the input data stream 210.

In one embodiment, the first signal 214 produced by the phase detector 202 generates a pulse once per data clock 212 period that indicates whether the data clock 212 leads or lags the midpoint of the corresponding input data stream 210 bit period. In one particular implementation, the first signal 214 is employed on two separate signal lines, one line which carries logic pulses indicating the data clock 212 leads the midpoint, and one line which carries logic pulses indicating the data clock 212 lags the midpoint. Many other methods for implementing the first signal 214 may be employed in alternative implementations.

In one embodiment, the phase detector 202 may determine the relative phase of the data clock 212 compared to its preferred phase once per period. In alternative embodiments, the data sampler may make this determination less often, such as once every two or more data clock 212 cycles.

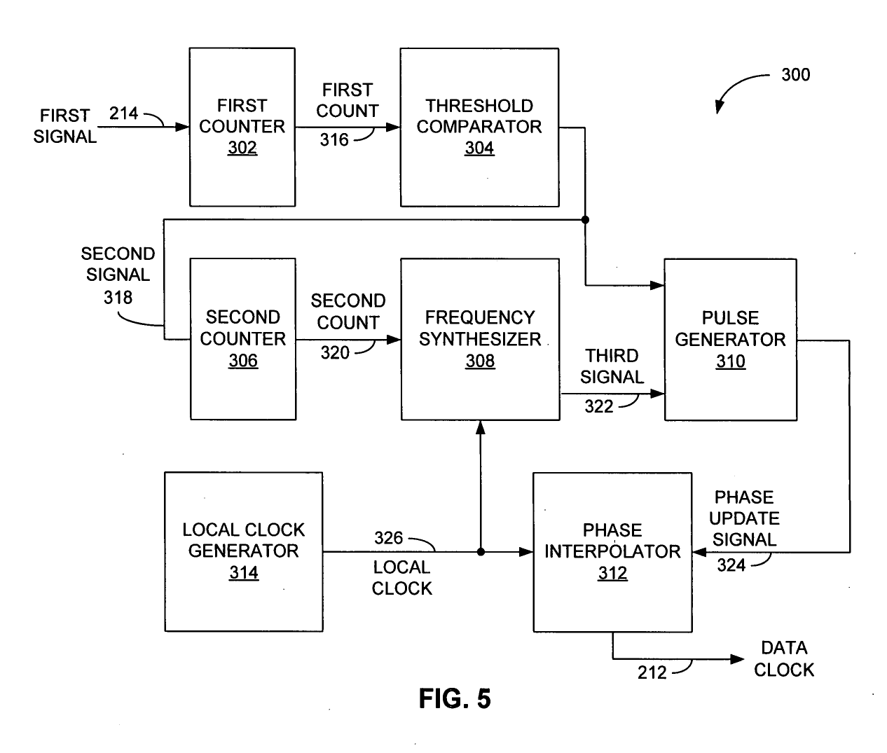

FIG. 5 illustrates one particular example of the phase controller 300 according to an embodiment of the invention. A first counter 302 generates a first count 316 from the first signal 214. The first counter 302, in one particular implementation, counts pulses of the first signal 214 to generate the first count 316. More specifically, each pulse indicating the data clock 212 lags the midpoint of the input data stream 210 may cause the first counter 302 to increment the first count 316, while each pulse denoting the data clock 212 lagging the midpoint may cause the first counter 302 to decrement the first count 316. In this case, the first count 316 represents a running value generally indicating the relative phase of the data clock 212 and its preferred phase to help determine if any correction of the data clock 212 phase is necessary to maintain the data integrity of any data received from the input data stream 210.

Continuing with FIG. 5, a threshold comparator 304 is configured to activate a second signal 318 when the first count 316 exceeds a threshold. In one embodiment, the threshold comparator 304 compares each value of the first count 316 against a threshold value. For example, in implementations in which the first count 316 changes once per data clock 212 period, the threshold comparator 304 may also perform the comparison once per data clock 212 period. In alternative implementations, the first count 316 may be updated less often, thus allowing the comparison to occur at a lower frequency.

If the first count 316 exceeds the threshold, the second signal 318 is activated, and the first counter 302 is reset, thus returning the first count 316 to a zero value. In one embodiment, activation occurs by way of a pulse indicating a direction for shifting the phase of the data clock 212 being generated for each data clock 212 period in which the first count 316 exceeds the threshold. For example, two signal lines may be employed for the second signal 318 such that pulses on one line indicate advancing the phase of the data clock 212, while pulses on the other line indicate delaying the phase. In that case, a positive value of the first count 316 that exceeds the threshold causes a pulse of the second signal 318 indicating advancement of the data clock 212 phase. Similarly, the absolute value of a negative first count 316 that exceeds the threshold generates a pulse of the second signal 318 indicating a desired delay in the phase of the data clock 212.

Generally, the first counter 302 and the threshold comparator 304 operate in tandem as a filter to prevent shifting the phase of the data clock 212 based upon each indication of the first signal 214. More specifically, a pattern of the data clock 212 leading or lagging the midpoint of several bit periods of the input data stream 210 may be required before activation of the second signal 318. In one embodiment, the threshold may range in value from 64 to 128. Without such filtering, slight alterations in phase difference between the data clock 212 and its preferred phase may cause unnecessary adjustments in the phase of the data clock 212.

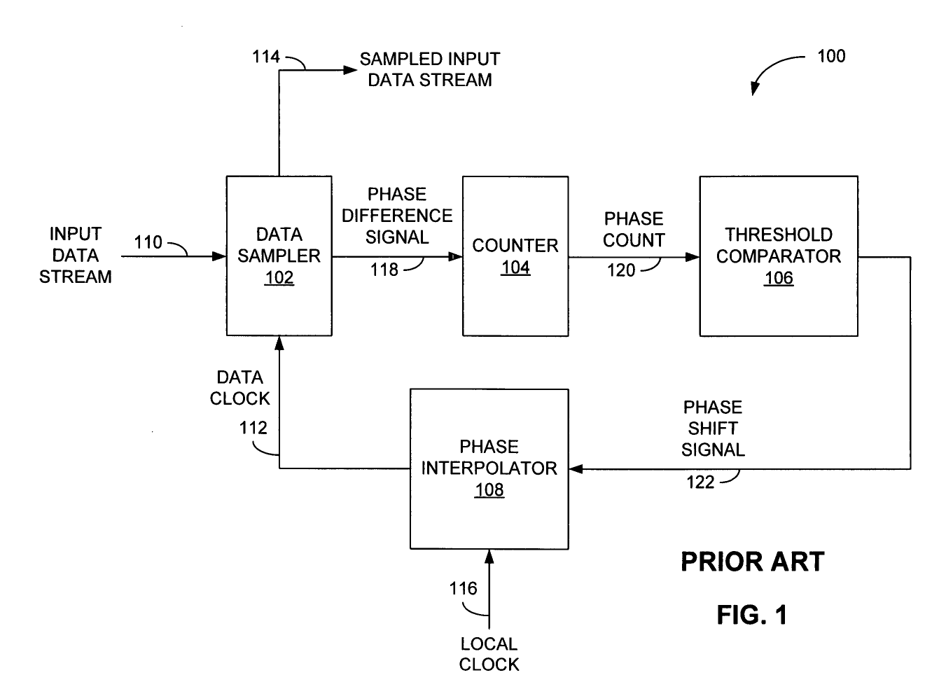

Unlike the phase shift signal 122 of the data clock recovery system 100 of FIG. 1, each pulse of the second signal 318 of the phase controller 300 does not directly indicate one increment of phase shift as provided by a phase interpolator. Instead, the second signal 318 drives the remainder of the phase controller 300, which processes the second signal 318 to shift the phase of the data clock 212 at a rate positively related to the length of time the second signal 318 indicates the data clock 212 leads or lags the input data stream 210. As described above, the second signal 318 indicates this lagging or leading by way of the first signal 214. In one implementation, for each pulse of the second signal 318, the phase of the data clock 212 may be shifted one or more phase increments, as is described in greater detail below.

The second signal 318 drives a second counter 306 which counts the number of pulses of the second signal 318 to generate a second count 320. More specifically, for each pulse of the second signal 318 that indicates advancing the phase of the data clock 212, the second count 320 is incremented by one, while a pulse of the second signal 318 that indicates delaying the phase of the data clock 212 causes the second count 320 to be decremented by one.

The second count 320 drives a frequency synthesizer 308 for generating a third signal 322 with pulses exhibiting a frequency positively related with the absolute value of the second count 320. In one embodiment, the frequency f is proportional to the absolute value of the second count 320:
f∝|2nd_count|

In a further embodiment, the frequency is the absolute value of the second count 320 multiplied by a programmable constant such that the overall frequency of the third signal 322 in response to the second count 320 may be altered:
f=(programmable_const)×|2nd_count|

Such alteration impacts how quickly the phase controller 300 modifies the phase of the data clock 212 in response to any sustained leading or lagging of the data clock 212 phase, thus enhancing the stability of the response of the phase controller 300 to phase changes between the input data stream 210 and the data clock 212. In one embodiment, the frequency synthesizer 308 generates at least one pulse for the third signal 322 per pulse of the second signal 318. As a result, higher absolute values of the second count 320 result in multiple pulses of the third signal 322 per a number of data clock 212 periods equal to the threshold. In a particular implementation, the third signal 322 may be comprised of two signal lines such that pulses on one line indicate advancing the phase of the data clock 212, while pulses on the other line indicate delaying the phase. As a result, a positive value of the second count 320 causes pulses of the third signal 322 to indicate advancement of the data clock 212 phase. Similarly, a negative second count 320 causes the generation of pulses of the second signal 318 indicating a desired delay in the phase of the data clock 212. Accordingly, a second count 320 of zero creates no pulses in the third signal 322.

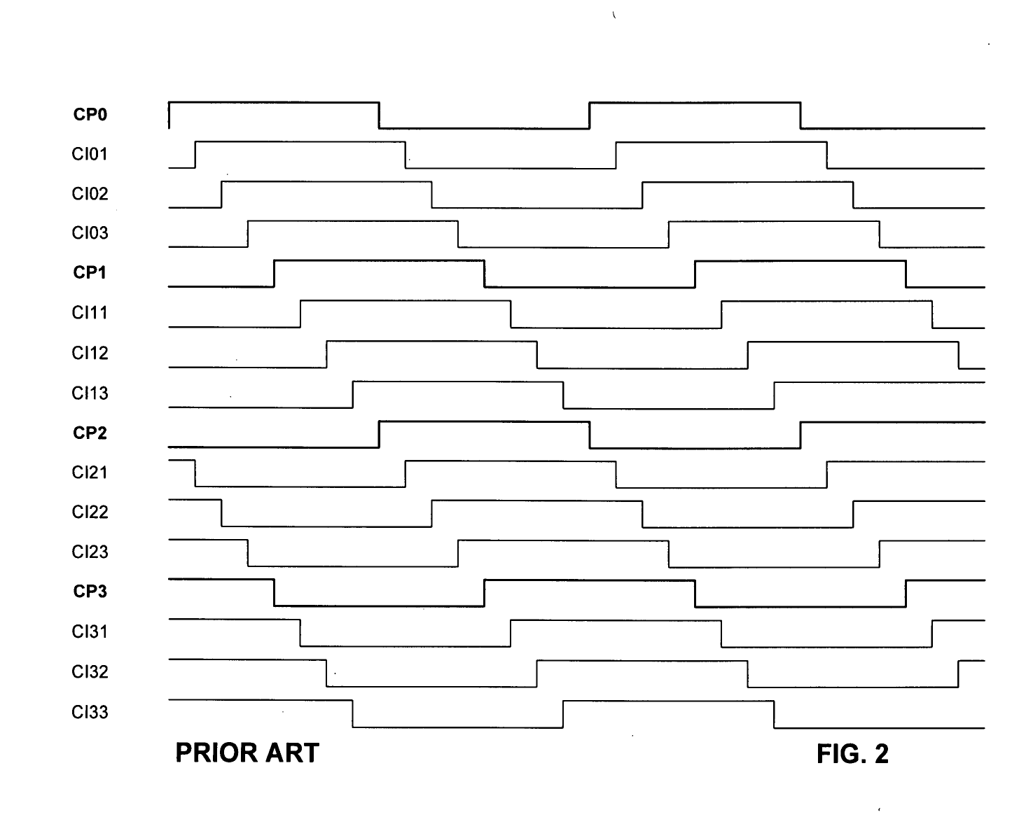

In one embodiment, the frequency synthesizer 308 is also driven by a local clock 326 supplied by a local clock generator 314. In some cases, the local clock 304 may be a multiphase local clock similar to the multiphase local clock 116 shown earlier in FIG. 2.

Referring again to FIG. 5, a pulse generator 310 employs the second signal 318 and the third signal 322 to generate a phase update signal 324. In one embodiment, the phase update signal 324 exhibits a pulse for each pulse of the second signal 318 and the third signal 322 to drive a phase interpolator 312. In a particular embodiment, the phase update signal 324 is propagated on two separate signal lines, one carrying pulses indicating advancement of the data clock 212, and one carrying pulses indicating delay of the data clock 212.

In one particular implementation of the pulse generator 310, the pulses of the second signal 318 and the third signal 322 are summed so that simultaneous arrival of pulses of the second signal 318 and the third signal 322 create a corresponding number of pulses for the phase update signal 324. More specifically, if a pulse of the second signal 318 and a simultaneous pulse of the third signal 322 both indicate advancement or delay of the data clock 212, two pulses of the phase update signal 324 indicating the corresponding direction of phase shift will be generated. Similarly, if simultaneous pulses of the second signal 318 and the third signal 322 indicate shifting the data clock 212 in opposing directions (e.g., the second signal 318 indicates delaying the data clock 212, while the third signal 322 denotes advancing the data clock 212), no pulses will be generated for the phase update signal 324 as a result. In summary, the action of the pulse generator 322 may be described by way of the truth table shown in Table 1:

TABLE 1
Pulse Generator 310 Truth Table

| Pulses of Phase | Second Signal | Second Signal | Second Signal |
|---|---|---|---|
| Update Signal 324 | 318 = Advance | 318 = Delay | 318 = Zero |
| Third Signal | Two Advance | No Pulses | One Advance |
| 322 = Advance | Pulses | | Pulse |
| Third Signal | No Pulses | Two Delay Pulses | One Delay |
| 322 = Delay | | | Pulse |
| Third Signal | One Advance | One Delay Pulse | No Pulses |
| 322 = Zero | Pulse | | |

In some embodiments of the invention, the pulses of the phase update signal 324 generated as a result of the third signal 322 provide a type of frequency shift of the data clock 212 to match the frequency of the input data stream 210, while pulses produced via the second signal 318 provide phase adjustment between the data clock 212 and the input data stream 210.

In an alternative embodiment, the third signal 322 may be transferred directly to the phase interpolator 312 as the phase update signal 324, thus eliminating the requirement of a pulse generator 310.

Each pulse of the phase update signal 324 instructs the phase interpolator 312 to advance or delay the phase of the data clock 212 by one phase “step.” In a further embodiment, the phase angle represented by a single step is determined by the number of clock phases provided by the phase interpolator 312. In one example, the phase interpolator 312 may be driven by a local clock 326 generated by the local clock generator 314 described above. The local clock 326 may be a clock supplying multiple phases, such as the clock phases CP0-CP3 shown in FIG. 2. In addition, the phase interpolator 312 may provide multiple interpolated clock phases CI01-CI03, CI11-CI13, CI21-CI23, and CI31-CI33 between corresponding phases of the local clock 326, thus providing a total of 16 phases from which to develop the data clock 212. In that case, each phase is separated from an adjacent phase by 22.5 degrees. In alternative embodiments, more or fewer clock phases, either interpolated or existing as a phase of a multiphase clock, may be utilized to similar end.

Any of the multiphase clock phases CP0-CP3 and the interpolated clock phases may be selected by the phase interpolator 312 at the direction of the phase update signal 324 for the data clock 212 to attain its preferred phase in relation to the input data stream 210. For example, if the current data clock 212 is interpolated clock CI23, and a pulse of the phase update signal 324 indicates that the data clock 212 should be advanced one step, the next leading phase, interpolated clock CI22, would become data clock 212. Conversely, if the current data clock 212 is the clock phase CP1, and the phase update signal 324 forces a delay of one step, the interpolated clock phase CI11 becomes the data clock 212.

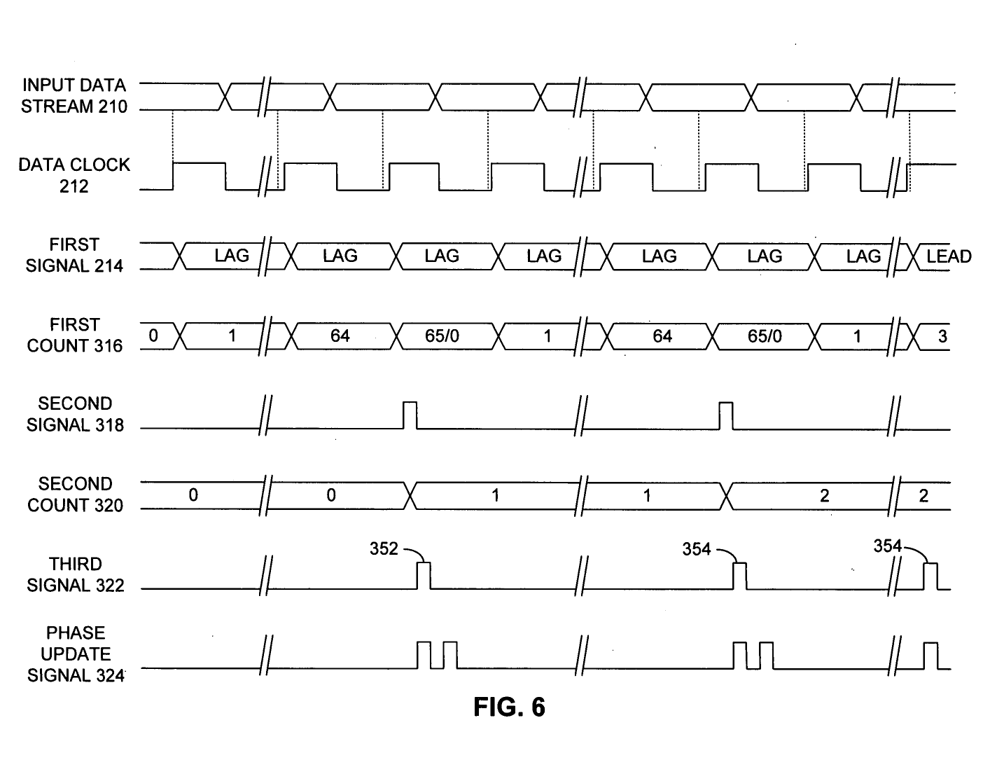

FIG. 6 provides a simplified timing diagram depicting the operation of the data clock recovery system 200 for a given input data stream 210 according to an embodiment of the invention. In this example, the frequency of the input data stream 210 is higher than that of the data clock 212, thus causing the data clock 212 to lag its preferred phase, shown graphically by the vertical dotted line segments in FIG. 6. The phase detector 202 indicates this by a “lag” indication every bit period of the input data stream 210 by way of the first signal 214. Assuming a threshold of 64, the first signal 214 causes the first counter 302 to provide a first count 316 rising to 65, resetting to zero, and counting up again, cyclically. Each time the first count 316 exceeds the threshold, the threshold comparator 304 produces a pulse for the second signal 318 indicating advancement of the data clock 212 is necessary. The repetitive generation of these pulses on the second signal 318 indicates that the data clock 112 continues to lag its preferred phase.

Each pulse of the second signal 318 indicating that the data clock 212 should be advanced increments the second count 320 by way of the second counter 306. As the second count 320 increases, the frequency of the third signal 322 increases. Thus, the second signal 318 pulses indicating desired advances in the data clock 212 phase, in combination with the increasing frequency of the third signal 322, cause the pulse generator 310 to generate a phase update signal 324 providing advancement pulses 352, 354 of increasing frequency to accelerate the phase shift of the data clock 212 in response to the higher frequency of the input data stream 210. In this particular example, the frequency of the third signal 322 when the second count 320 is two (i.e., pulses 354) is substantially twice the frequency of the third signal 322 when the second count is one (i.e., pulses 352). In one embodiment, the pulses of the third signal 322 occur once every several bit periods when the second count 320 is one, and increase linearly according to the second count 320 value. Further, as shown in FIG. 6, the number of advancement pulses of the phase update signal 324 is equal to the sum of the number of pulses of both the second signal 318 and the third signal 322. To this end, when the second signal 318 and the third signal 322 produce advancement pulses essentially simultaneously, two advancement pulses of the phase update signal 324 are produced serially.

As long as the data clock 212 continues to lag its preferred phase, as indicated by the first signal 214, higher frequencies for the third signal 322 proportional to the second count 320 will continue to be provided. However, once a frequency for the third signal 322 has been achieved to allow the first signal 214 to detect bit periods in which the data clock 212 leads its preferred phase, as shown in FIG. 6, the second signal 318 ceases production of pulses to advance the phase of the data clock 212. As a result, the second count 320 will typically maintain a narrow range of values, allowing the third signal 322 to maintain a range of frequencies for updating the phase of the data clock 212 over an extended number of bit periods. In the particular example of FIG. 6, a second count 320 of about 2 provides approximately the number of update pulses 354 for the data clock 212 to maintain the preferred phase with the input data stream 210. Thus, as long as the frequency of the input data stream 210 remains substantially constant, the phase controller 300 will achieve a type of steady state in updating the phase of the data clock 212 so that it will remain near its preferred phase.

FIG. 6 specifically presents an example of the data clock 212 having a frequency less than that of the input data stream 210, so that the phase controller 300 must continually advance the phase of the data clock 212 to maintain the preferred phase. In other cases, the frequency of the data clock 212 may be greater than that of the input data stream 210, thus causing the phase controller 300 to delay the data clock 212 phase aggressively so that the preferred phase for the data clock 212 will be maintained under those circumstances as well.

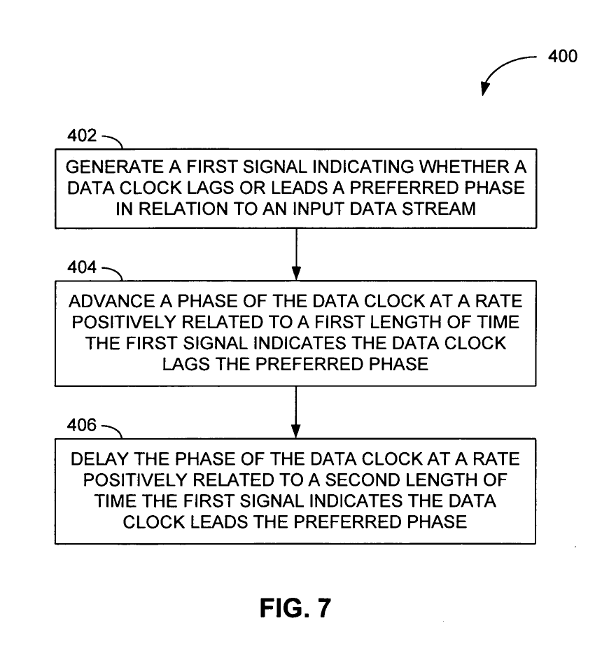

In another embodiment of the invention, a method 400 for recovering data clock information from a communication signal is presented in FIG. 7. A first signal indicating whether a data clock lags or leads a preferred phase in relation to an input data stream is generated (operation 402). In a particular embodiment, the preferred phase of the data clock aligns with the midpoint between logic transitions of the input data stream. The phase of the data clock is advanced at a rate positively related to the length of time the first signal indicates the data clock lags the preferred phase (operation 404). Conversely, the phase of the data clock is delayed at a rate positively related to the length of time the first signal indicates the data clock leads the preferred phase (operation 406).

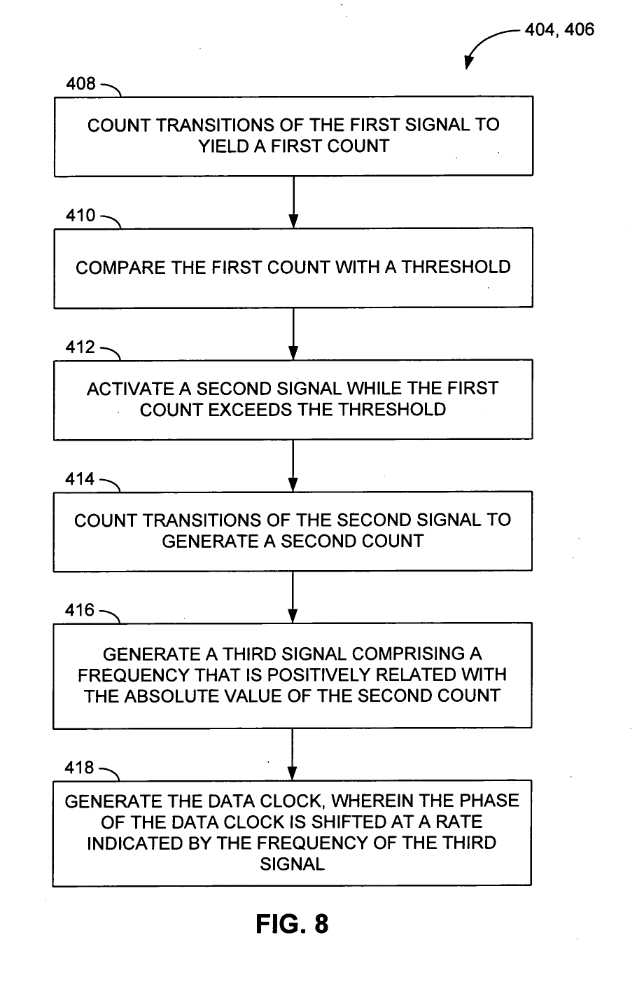

FIG. 8 is a flow chart of how the first signal may be processed in operations 404 and 406 according to a particular embodiment of the invention in order to shift the phase of the data clock. Transitions of the first signal are counted to yield a first count (operation 408), which is compared with a threshold (operation 410). A second signal is activated while the first count exceeds the threshold (operation 412). Transitions of the second signal are then counted to generate a second count (operation 414). A third signal having a frequency positively related with the absolute value of the second count is then generated (operation 416). In one implementation, the third signal has a frequency proportional to the absolute value of the second count. The data clock is generated so that its phase is shifted at a rate indicated by the frequency of the third signal (operation 418). In one embodiment, the phase of the data clock is shifted according to both the second signal and the third signal.

Referring again to FIG. 4, by shifting the phase of the data clock 212 at a rate positively related to the length of time the data clock 212 leads or lags its preferred phase, extensive and continual shifting of the data clock 212 may occur. As a result, tracking of extensive frequency offsets between the data clock 212 and the input data stream 210 may occur, thus providing a wide frequency tracking range. Therefore, accurate sampling and acquisition of data embodied in the input data stream 210 is not prevented by large, persistent offsets in frequencies of the data clock 212 and the input data stream 210 when embodiments of the system 200 are employed.

Embodiments of the invention described above, as well as alternatives thereof, may be implemented by way of an application-specific integrated circuit (ASIC), a digital signal processor (DSP), a microprocessor, a microcontroller, or any other electronic circuit capable of employing the various functions described while obeying any timing constraints imposed by a particular application.

While several embodiments of the invention have been discussed herein, other embodiments encompassed by the scope of the invention are possible. For example, while embodiments disclosed herein employ particular signaling conventions, such as the clocking an input data stream on a rising logic transition, many other signaling conventions may be employed in the alternative. Also, while several different types of electronic components have been referenced, others capable of performing the same or similar functions may be employed as well. Further, aspects of one embodiment may be combined with those of alternative embodiments to create further implementations of the present invention. Thus, while the present invention has been described in the context of specific embodiments, such descriptions are provided for illustration and not limitation. Accordingly, the proper scope of the present invention is delimited only by the following claims.

What is claimed is:

1. A data clock recovery system, comprising:
a phase detector configured to produce a first signal indicating whether a data clock lags or leads a preferred phase in relation to an input data stream; and
a phase controller configured to process the first signal to shift a phase of the data clock toward the preferred phase at a rate positively related to a length of time the data clock lags or leads the preferred phase.

2. The system of claim 1, the phase controller comprising:
a first counter configured to generate a first count from the first signal;
a threshold comparator configured to activate a second signal when the first count exceeds a threshold;
a second counter configured to generate a second count from the second signal;
a frequency synthesizer configured to generate a third signal comprising a frequency that is positively related with an absolute value of the second count; and
a phase interpolator configured to generate the data clock, wherein the phase of the data clock is shifted according to the third signal.

3. The system of claim 1, the phase controller comprising:
a first counter configured to generate a first count from the first signal;
a threshold comparator configured to activate a second signal when the first count exceeds a threshold;
a second counter configured to generate a second count from the second signal;
a frequency synthesizer configured to generate a third signal comprising a frequency that is positively related with an absolute value of the second count;
a pulse generator configured to generate a pulse update signal comprising a pulse for each pulse of the second signal and the third signal; and
a phase interpolator configured to generate the data clock, wherein the phase of the data clock is shifted according to the phase update signal.

4. The system of claim 3, wherein the frequency of the third signal is proportional to the absolute value of the second count.

5. The system of claim 3, wherein the frequency synthesizer and the phase interpolator are configured to be driven by a local clock.

6. The system of claim 5, wherein the local clock comprises a multiphase local clock.

7. The system of claim 1, wherein the preferred phase of the data clock comprises a midpoint between logical transitions of the input data stream.

8. The system of claim 1, wherein the phase detector produces the first signal by way of sampling the input data stream with a plurality of phases of the data clock.

9. The system of claim 3, wherein the second signal comprises a pulse when the first count exceeds the threshold.

10. The system of claim 1, wherein the input data stream comprises a serial input data stream.

11. The system of claim 1, wherein the input data stream comprises a parallel input data stream.

12. The system of claim 1, wherein the system is implemented by way of one of an application-specific integrated circuit, a digital signal processor, a microprocessor, and a microcontroller.

13. A data communication system comprising the system of claim 1.

14. A method for recovering data clock information from a communication signal, the method comprising:
generating a first signal indicating whether a data clock lags or leads a preferred phase in relation to an input data stream;
advancing a phase of the data clock at a rate positively related to a first length of time the first signal indicates the data clock lags the preferred phase; and
delaying the phase of the data clock at a rate positively related to a second length of time the first signal indicates the data clock leads the preferred phase.

15. The method of claim 14, wherein advancing and delaying the phase of the data clock comprises:
counting transitions of the first signal to yield a first count;
comparing the first count with a threshold;
activating a second signal while the first count exceeds the threshold;
counting transitions of the second signal to generate a second count;
generating a third signal comprising a frequency that is positively related with the absolute value of the second count; and
generating the data clock, wherein the phase of the data clock is shifted at a rate indicated by the frequency of the third signal.

16. The method of claim 15, wherein the frequency of the third signal is proportional to the absolute value of the second count.

17. The method of claim 15, wherein the phase of the data clock is also shifted according to the second signal.

18. The method of claim 15, further comprising generating a local clock from which the data clock is generated.

19. The method of claim 18, wherein the local clock comprises a multiphase local clock.

20. The method of claim 14, wherein the preferred phase comprises a midpoint between transitions of the input data stream.

21. The method of claim 14, wherein generating the first signal comprises comparing the phase of the input data stream with a plurality of phases of the data clock.

22. The method of claim 15, wherein the second signal comprises a pulse when the first count exceeds the threshold.

23. The method of claim 14, wherein the input data stream comprises a serial input data stream.

24. The method of claim 14, wherein the input data stream comprises a parallel input data stream.

25. The method of claim 14, wherein the method is executed by way of one of an application-specific integrated circuit, a digital signal processor, a microprocessor, and a microcontroller.

26. A data communication system comprising the method of claim 14.

27. A data clock recovery system, comprising:
means for generating a first signal indicating whether a data clock lags or leads a preferred phase in relation to an input data stream; and
means for shifting a phase of the data clock toward the preferred phase at a rate that is positively related to a length of time the first signal indicates the data clock leads or lags the preferred phase.

28. The system of claim 27, wherein means for shifting the phase of the data clock comprises:
means for generating a first count based on the first signal;
means for comparing the first count with a threshold;
means for counting each time the first count exceeds the threshold;
means for generating a third signal comprising a frequency that is positively related with the absolute value of the second count; and
means for generating the data clock, wherein the phase of the data clock is shifted at a rate corresponding to the frequency of the third signal.

29. The system of claim 28, wherein the frequency of the third signal is proportional to the absolute value of the second count.

30. The system of claim 28, further comprising means for generating a local clock from which the data clock is generated.

31. The system of claim 30, wherein the local clock comprises a multiphase local clock.

32. The system of claim 27, wherein the preferred phase comprises a midpoint between transitions of the input data stream.

33. The system of claim 27, wherein means for generating the first signal comprises means for comparing a phase of the input data stream with a plurality of phases of the data clock.

34. The system of claim 27, wherein the input data stream comprises a serial input data stream.

35. The system of claim 27, wherein the input data stream comprises a parallel input data stream.

36. The system of claim 27, wherein the system is implemented by way of one of an application-specific integrated circuit, a digital signal processor, a microprocessor, and a microcontroller.

37. A data communication system comprising the system of claim 27.
